(19) United States
(12) Patent Application Publication
(10) Pub. No.: US 2025/0234720 A1
(43) Pub. Date: Jul. 17, 2025

(54) OVERHANG PATTERN FOR ADVANCED OLED PATTERNING

(71) Applicant: Applied Materials, Inc., Santa Clara, CA (US)

(72) Inventors: JUNGMIN LEE, Santa Clara, CA (US); Dieter HAAS, Santa Clara, CA (US); Grgory Max MCDANIEL, San Jose, CA (US); Yu-Hsin LIN, Zhubei City (TW)

(21) Appl. No.: 19/006,989

(22) Filed: Dec. 31, 2024

Related U.S. Application Data
(60) Provisional application No. 63/621,416, filed on Jan. 16, 2024.

(51) Int. Cl. H10K 59/122; H10K 59/12; H10K 59/80; H10K 102/00

(52) U.S. Cl. CPC H10K 59/122; H10K 59/1201; H10K 59/80521; H10K 2102/361

(57) ABSTRACT

Embodiments described herein relate to a sub-pixel circuit and methods of forming a sub-pixel circuit. The sub-pixel circuit include adjacent overhang structures, an anode, an organic light emitting diode (OLED) material disposed over the anode, and a cathode disposed over the OLED material. The OLED material extends under the adjacent overhang structures. The cathode extends under the adjacent overhang structures. The overhang structures are defined by an overhang extension of a second structure extending laterally past a first structure. The first structure is disposed over a substrate. The first structure includes a lower section having a first lateral etching rate and an upper section deposited over the lower section having a second lateral etching rate. The second lateral etching rate is different from the first lateral etching rate.

### CROSS-REFERENCE TO RELATED APPLICATIONS

This application claim benefit of and priority to U.S. Provisional Patent Application No. 63/621,416, filed Jan. 16, 2024, which is hereby expressly incorporated by reference in its entirety as if fully set forth below and for all applicable purposes.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography can be used to pattern pixels. Currently, OLED pixel patterning requires lifting off organic material after the patterning process. When lifted off, the organic material leaves behind particle that disrupt OLED performance. Accordingly, what is needed in the art are sub-pixel circuits and methods of forming sub-pixel circuits to increase pixel-per-inch and provide improved OLED performance.

### SUMMARY

In one embodiment, a sub-pixel circuit is disclosed. The sub-pixel circuit include adjacent overhang structures, an anode, an organic light emitting diode (OLED) material disposed over the anode, and a cathode disposed over the OLED material. The OLED material extends under the adjacent overhang structures. The cathode extends under the adjacent overhang structures. The overhang structures are defined by an overhang extension of a second structure extending laterally past a first structure. The first structure is disposed over a substrate. The first structure includes a lower section having a first lateral etching rate and an upper section deposited over the lower section having a second lateral etching rate. The second lateral etching rate is different from the first lateral etching rate.

In another embodiment, a device is disclosed. The device includes a substrate, a plurality of adjacent pixel-isolation structures (PIS) disposed over the substrate, and a plurality of sub-pixels. Each sub-pixel includes adjacent overhang structures, an anode, an organic light emitting diode (OLED) material disposed over the anode, and a cathode disposed over the OLED material. The overhang structures are defined by an overhang extension of a second structure extending laterally past a first structure. The first structure is disposed over a substrate. The first structure includes a first endpoint of a bottom surface of the first structure, a second endpoint of the bottom surface of the first structure, a lower section having a first lateral etching rate, and an upper section deposited over the lower section having a second lateral etching rate. The first endpoint extends to or past a first edge of the PIS and the second endpoint extends to or past a second edge the PIS. The second lateral etching rate is different from the first lateral etching rate. The OLED material extends under the adjacent overhang structures. The cathode extending under the adjacent overhang structures.

In another embodiment, a method of forming a sub-pixel circuit as is disclosed. The method includes disposing a lower section layer having a first lateral etching rate over a substrate. An anode is deposited on the substrate. An upper section layer having a second lateral etching rate is disposed over the lower section layer. The first lateral etching rate is different from the second lateral etching rate. The lower section layer and the upper section layer form a first structure layer. A second structure layer is disposed over the first structure layer. Portions of the first structure layer and the second structure layer exposed by a resist are removed to form adjacent overhang structures defined by an overhang extension of a second structure formed from the second structure layer extending laterally past a first structure formed from the first structure layer. The first structure is disposed over the substrate. The first structure includes an upper section formed from the upper section layer and a lower section formed from the lower section layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a schematic, cross-sectional view of a sub-pixel circuit, according to embodiments.

FIG. 1B is a schematic, cross-sectional view of an overhang structure of a sub-pixel circuit, according embodiments.

FIG. 2 is a flow diagram of a method of forming the sub-pixel circuit, according to embodiments.

FIGS. 3A-3J are schematic, cross-sectional views of a substrate during the method of FIG. 2 for forming the sub-pixel circuit, according to embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display.

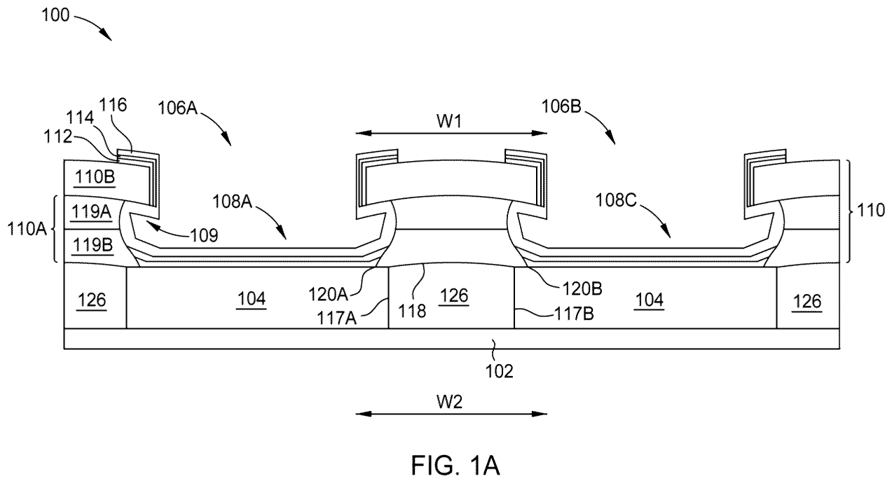

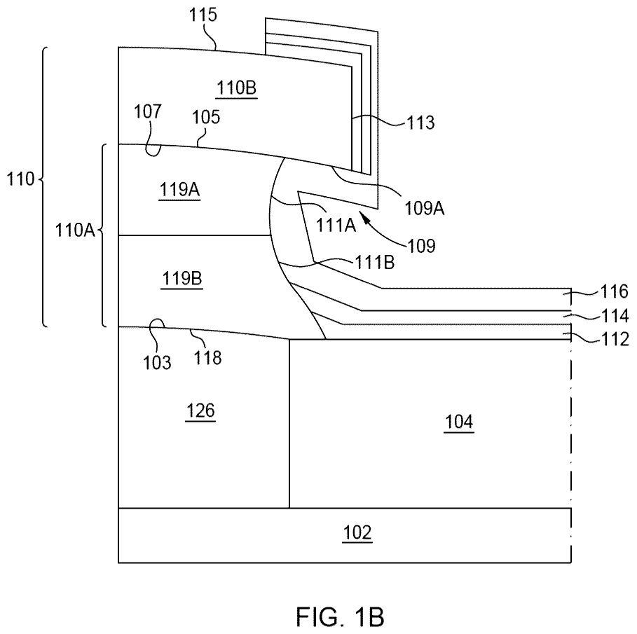

FIG. 1A is a schematic, cross-sectional view of a sub-pixel circuit 100. FIG. 1B is a schematic, cross-sectional view of an overhang structure 110 of a sub-pixel circuit 100. The sub-pixel circuit 100 includes a substrate 102. A base layer (not shown) may be patterned over the substrate 102. The base layer includes, but is not limited to, a CMOS layer. Metal-containing layers (e.g., an anode 104) may be patterned on the substrate 102 (or, if there is a base layer, the anode 104 may be patterned on the base layer) and are defined by adjacent pixel isolation structures (PIS) 126 disposed over the substrate 102. In one embodiment, the anode 104 is pre-patterned on the substrate 102 (or base layer). E.g., the substrate 102 is pre-patterned with anode 104 of indium tin oxide (ITO). The anode 104 is configured to operate as an anode of respective sub-pixels. In one embodiment, the anode 104 is a layer stack of a first transparent conductive oxide (TCO) layer, a second metal-containing layer disposed on the first TCO layer, and a third TCO layer disposed on the second metal-containing layer. The anode 104 includes, but is not limited to, chromium, titanium, gold, silver, copper, aluminum, ITO, a combination thereof, or other suitably conductive materials.

The PIS 126 are disposed over the substrate 102. The PIS 126 may be disposed on the substrate 102 (or the base layer). The PIS 126 include one of an organic material, an organic material with an inorganic coating disposed thereover, or an inorganic material. The organic material of the PIS 126 includes, but is not limited to, polyimides. The inorganic material of the PIS 126 includes, but is not limited to, silicon oxide (SiO₂), silicon nitride (Si₃N₄), silicon oxynitride (Si₂N₂O), magnesium fluoride (MgF₂), or combinations thereof. Adjacent PIS 126 define a respective sub-pixel and expose the anode 104 of the respective sub-pixel circuit 100.

The sub-pixel circuit 100 has a plurality of sub-pixel lines (e.g., first sub-pixel line 106A and second sub-pixel line 106B). The sub-pixel lines are adjacent to each other along a pixel plane. Each sub-pixel line includes at least two sub-pixels. E.g., the first sub-pixel line 106A includes a first sub-pixel 108A and a second sub-pixel (not shown) and the second sub-pixel line 106B includes a third sub-pixel 108C and a fourth sub-pixel (not shown). While FIG. 1A depicts the first sub-pixel line 106A and the second sub-pixel line 106B, the sub-pixel circuit 100 of the embodiments described herein may include two or more sub-pixel lines, such as a third sub-pixel line and a fourth sub-pixel line. Each sub-pixel line has OLED materials configured to emit a white, red, green, blue, or other color light when energized. For example, the OLED materials of the first sub-pixel line 106A emits a red light when energized, the OLED materials of the second sub-pixel line 106B emits a green light when energized, the OLED materials of a third sub-pixel line emits a blue light when energized, and the OLED materials of a fourth sub-pixel emits another color light when energized. The OLED materials within a pixel line may be configured to emit the same color light when energized. For example, the OLED materials of the first sub-pixel 108A and the second sub-pixel of the first sub-pixel line 106A emit a red light when energized and the OLED materials of the third sub-pixel 108C and the fourth sub-pixel of the second sub-pixel line 106B emit a green light when energized.

Each sub-pixel line includes adjacent overhang structures 110, with adjacent sub-pixel lines sharing the adjacent overhang structures 110. The overhang structures 110 are permanent to the sub-pixel circuit 100. The overhang structures 110 further define each sub-pixel line of the sub-pixel circuit 100. Each overhang structure 110 includes adjacent overhangs 109. The adjacent overhangs 109 are defined by an overhang extension 109A of a second structure 110B extending laterally past an upper surface 105 of a first structure 110A. The first structure 110A is disposed over an upper surface 103 of the PIS 126. A first endpoint 120A of a bottom surface 118 of the first structure 110A may extend to or past a first edge 117A of the PIS 126. A second endpoint 120B of the bottom surface of the first structure 110A may extend to or past a second edge 117B the PIS 126. The first structure 110A includes an upper section 119A and a lower section 119B. The upper section 119A is disposed over the lower section 119B. The thickness ratio of the upper section 119A to the lower section 110B is about 1:1 to about 1:2. The first structure 110A has a total thickness of about 150 nm to about 250 nm. The upper section 119A has a greater width adjacent to the second structure 110B and a lesser width adjacent to the lower section 119B. The lower section 119B has a greater width adjacent to the PIS 126 and a lesser width adjacent to the upper section 119A. The upper section 119A has an upper section sidewall 111A and the lower section 119B has a lower section sidewall 111B. The upper section sidewall 111A of the upper section 119A and the lower section sidewall 111B of the lower section 119B may be sloped or curved.

The second structure 110B is disposed over the upper section 119A of the first structure 110A. The second structure 110B may be disposed on the upper surface 105 of the first structure 110A. The bottom surface 107 and the upper surface 115 of the second structure 110B may be sloped or curved. The second structure has a width W1 of about 0.5 μm to about 2 μm, such as about 1 μm. The bottom surface 118 of the lower section 119B of the first structure 110A has a width W2 of about 0.5 μm to about 2 μm, such as about 1 μm. The width W2 of the bottom surface 118 is approximately equal to the width W1 of the second structure 110B.

The width W2 of the bottom surface 118 being approximately equal to the width W1 of the second structure 110B and extending to or past a first edge 117A and a second edge 117B of the PIS 126 reduces the likelihood of an abrupt step at the interface of the anode 104 and the first structure 110A, and thus reduces the likelihood of failure.

The second structure 110B may also be disposed over an intermediate structure. The intermediate structure may be disposed over the upper surface 105 of the first structure 110A. The intermediate structure may be a seed layer or an adhesion layer. The seed layer functions as a current path for the sub-pixel circuit 100. The seed layer may include a titanium (Ti) material. The adhesion promotion layer improves adhesion between the first structure 110A and the second structure 110B. The adhesion layer may include a chromium (Cr) material.

In one embodiment, which may be combined with other embodiments, the overhang structures 110 include the second structure 110B of a conductive inorganic material and the first structure 110A of a non-conductive inorganic material. The conductive materials of the second structure 110B include a copper (Cu), chromium (Cr), aluminum (Al), aluminum neodymium (AINd), molybdenum (Mo), molybdenum tungsten (MoW), or combinations thereof. The non-conductive materials of the first structure 110A include amorphous silicon (a-Si), silicon nitride (Si₃N₄), silicon oxide (SiO₂), silicon oxynitride (Si₂N₂O), or combinations thereof. The overhang structures 110 are able to remain in place, i.e., are permanent.

In another embodiment, the second structure includes inorganic materials. The inorganic materials of the second structure include titanium (Ti), silicon nitride (Si₃N₄), silicon oxide (SiO₂), silicon oxynitride (Si₂N₂O), or combinations thereof. The first structure includes conductive materials. The conductive materials of the first structure 110A include aluminum (Al), aluminum neodymium (AlNd), molybdenum (Mo), molybdenum tungsten (MoW), copper (Cu), or combinations thereof.

The lower section 119B is deposited at a first temperature and the upper section 119A is deposited at a second temperature. In some embodiments, the first temperature and the second temperature are different. The first temperature may be from about 250° C. to about 350° C., such as 295° C. to 305° C. The second temperature may be from about 100° C. to about 200° C., such as about 145° C. to about 155° C. Depositing at a first temperature results in the lower section 119B having a first lateral etch rate, while depositing at a second temperature results in the upper section 119A having a second lateral etching rate. In one embodiment, the lower section 119B is an amorphous silicon, a silicon nitride, or a silicon oxide, and the upper section 119A is an amorphous silicon. The higher deposition temperature of the material of the lower section 119B results in the lower section 119B of the first structure 110A having a higher density that the upper section 119A of the first structure 110A. The higher density enables a slower etch rate of the lower section 119B, resulting in a decrease lateral etching. For examples, the etch rate of the upper section 119A is about 2 times to about 3 time greater than the etch rate of the lower section 119B. In some examples, the etch rate of the upper section 119A is about 3 nm/sec while the etch rate of the lower section 119B is about 1 nm/sec. The decrease in lateral etching reduces the likelihood that the lower section 119B is overly etched in the lateral direction, resulting in a decrease in likelihood of PIS exposure, and thus decreases the likelihood of sub-pixel circuit failure.

The adjacent overhangs 109 are defined by the overhang extension 109A. At least a bottom surface 107 of the second structure 110B is wider than the upper surface 105 of the first structure 110A to form the overhang extension 109A. The overhang extension 109A of the second structure 110B forms the overhang 109 and allows for the second structure 110B to shadow the first structure 110A. The shadowing of the overhang 109 provides for evaporation deposition of an OLED material 112 and a cathode 114. The OLED material 112 may include one or more of a HIL, a HTL, an EML, and an ETL. The OLED material 112 is disposed over and in contact with the anode 104. In some embodiments, the OLED material 112 is disposed under adjacent overhangs 109 and may contact the lower section sidewall 111B of the lower section 119B. In other embodiments, the OLED material 112 is disposed under adjacent overhangs 109 and may contact the lower section sidewall 111B of the lower section 119B and the upper section sidewall 111A of the upper section 119A. For example, the OLED material 112 is different from the material of the first structure 110A, the second structure 110B, and the intermediate structure.

The cathode 114 is disposed over the OLED material 112 and extends under the adjacent overhangs 109. The cathode 114 extends past an endpoint of the OLED material 112. For example, the cathode 114 may contact the lower section sidewall 111B of the lower section 119B. In other embodiments, the cathode 114 may contact the lower section sidewall 111B of the lower section 119B and the upper section sidewall 111A of the upper section 119A. The overhang structures 110 and an evaporation angle set by an evaporation source define deposition angles, i.e., the overhangs 109 provide for a shadowing effect during evaporation deposition with the evaporation angle set by the evaporation source.

The cathode 114 includes a conductive material, such as a metal. For example, the cathode 114 includes, but is not limited to, silver, magnesium, chromium, titanium, aluminum, ITO, or a combination thereof. In one embodiment, material of the cathode 114 is different from the material of the first structure 110A, the second structure 110B, and intermediate structure. In some embodiments, the OLED material 112 and the cathode 114 are disposed over a sidewall 113 of the second structure 110B of the overhang structures 110. In other embodiments, the OLED material 112 and the cathode 114 are disposed over an upper surface 115 of the second structure 110B of the overhang structures 110. In still other embodiments, the OLED material 112 and the cathode 114 end on one of the lower section sidewall 111B or the upper section sidewall 111A, i.e., are not disposed over the sidewall 113 of the second structure 110B or the upper surface 115 of the second structure 110B.

Each sub-pixel includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the overhangs 109 and along the upper section sidewall 111A and the lower section sidewall 111B of the first structure 110A and the sidewall 113 of the second structure 110B. In some embodiments, the encapsulation layer 116 extends to contact the lower section sidewall 111B of the first structure 110A. In some embodiments, the encapsulation layer 116 extends to contact the upper section sidewall 111A and the lower section sidewall 111B of the first structure 110A. In some embodiments, the encapsulation layer 116 extends to contact the second structure 110B at an underside surface of the overhang extension 109A. In some embodiments, the encapsulation layer 116 ends at the one of the upper section sidewall 111A or the lower section sidewall 111B, i.e., is not disposed over the sidewall 113 of the second structure 110B, the upper surface 115 of the second structure 110B, or the underside surface of the overhang extension 109A of the overhang structures 110. The encapsulation layer 116 includes the non-conductive inorganic material, such as the silicon-containing material. The silicon-containing material may include Si₃N₄ containing materials.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the sub-pixel circuit 100 further includes at least a global passivation layer disposed over the overhang structure 110 and the encapsulation layer 116. In yet another embodiment, the sub-pixel includes an intermediate passivation layer disposed over the overhang structures 110 of each of the sub-pixels 106, and disposed between the encapsulation layer 116 and the global passivation layer.

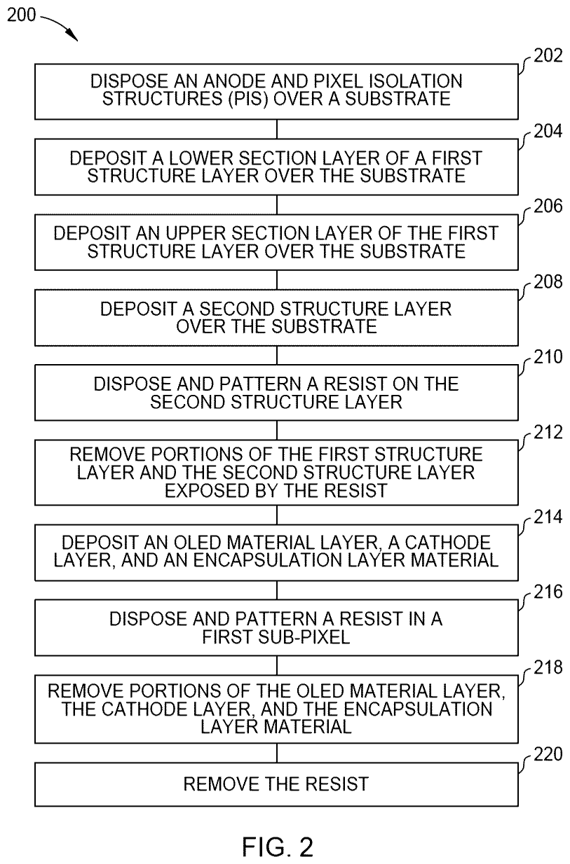

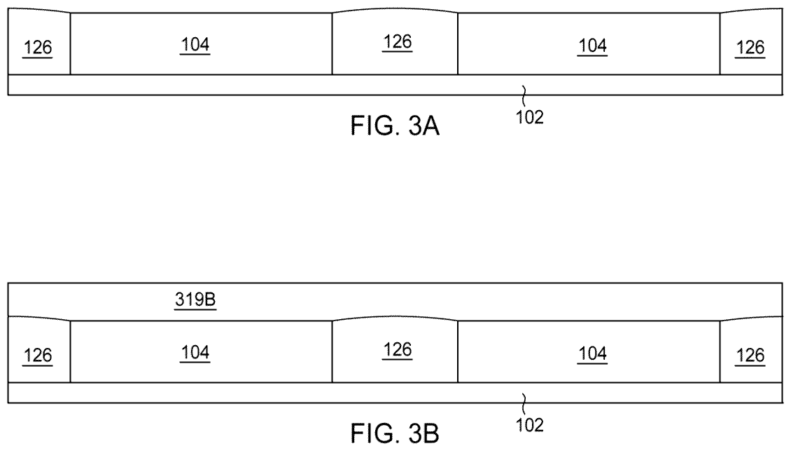

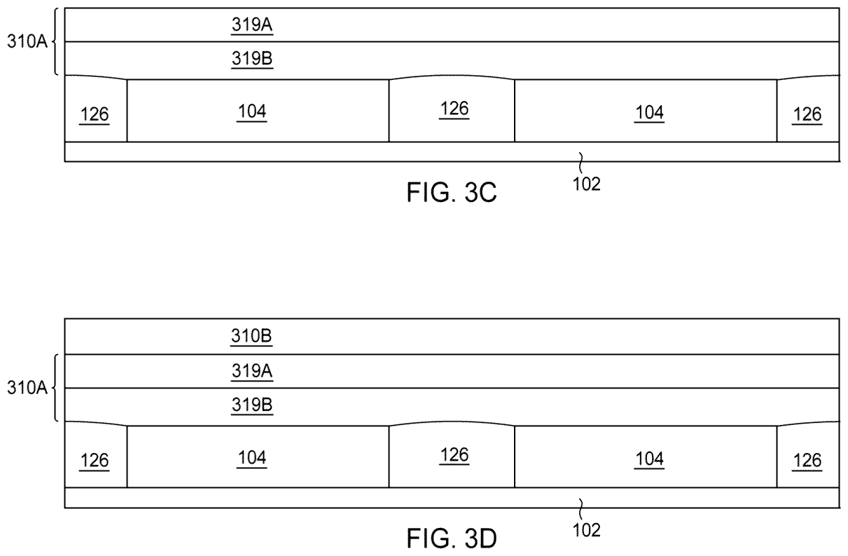

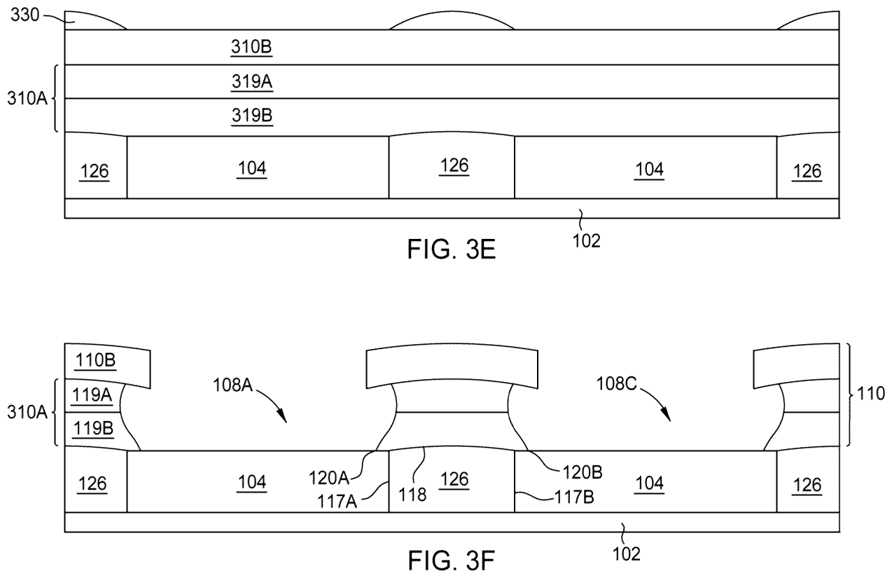

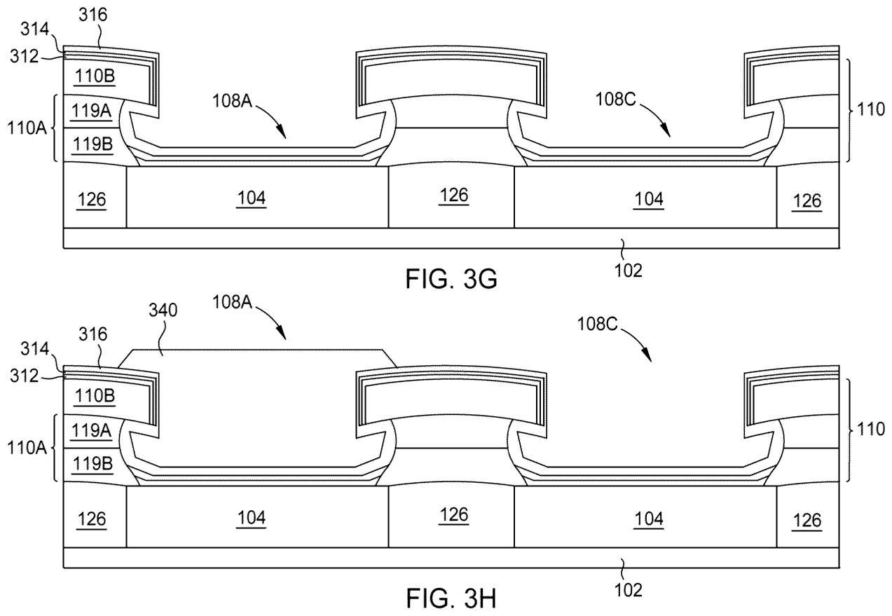

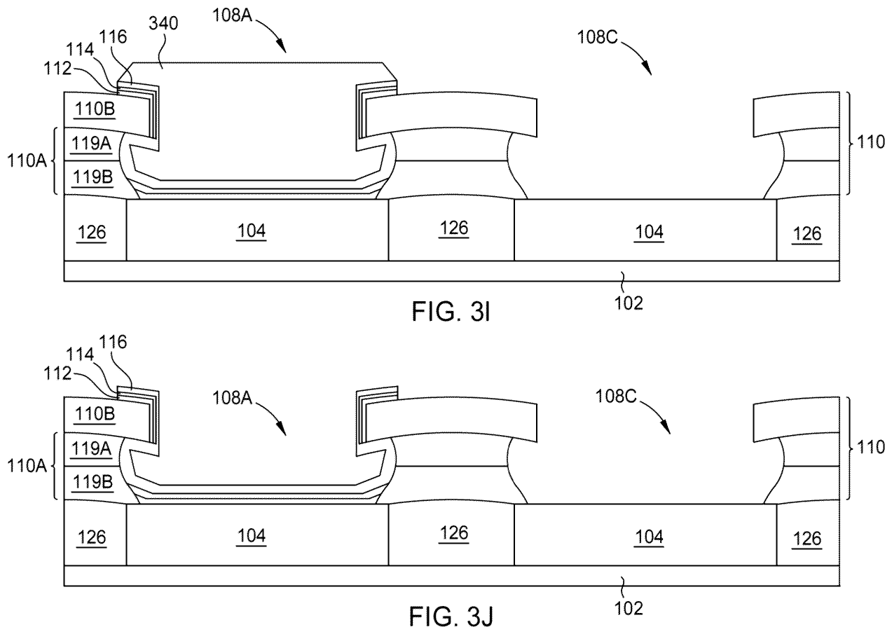

FIG. 2 is a flow diagram of a method 200 of forming the sub-pixel circuit 100. FIGS. 3A-3J are schematic, cross-sectional views of a substrate 102 during the method 200 for forming the sub-pixel circuit 100.

At operation 202, as shown in FIG. 3A, a metal-containing layer (e.g., anode 104) and a plurality of pixel-isolation structures (PIS) 126 are disposed over a substrate 102. The anode 104 may be deposited on the substrate 102. The anode 104 may be deposited using metal-organic decomposition (MOD). The plurality of PIS 126 separate the anode 104 from an adjacent anode 104. The plurality of PIS 126 are deposited over the substrate 102. The thickness of the anode 104 is about 200 nm to about 300 nm, such as about 250 nm.

At operation 204, as shown in FIG. 3B, a lower section layer 319B of a first structure layer 310A is deposited over the substrate 102. The lower section layer 319B is deposited using chemical vapor deposition (CVD). The lower section layer 319B has a thickness of about 100 nm to about 250 nm, such as about 150 nm to about 200 nm. The lower section layer 319B is deposited at a first temperature of about 250° C. to about 350° C., such as 300° C. The lower section layer 319B includes amorphous silicon (a-Si), silicon nitride (Si₃N₄), silicon oxide (SiO₂), silicon oxynitride (Si₂N₂O), or combinations thereof.

At operation 206, as shown in FIG. 3C, an upper section layer 319A of a first structure layer 310A is deposited over the lower section layer 319B. The upper section layer 319A is deposited using chemical vapor deposition (CVD). The upper section layer 319A has a thickness of about 100 nm to about 250 nm, such as about 150 nm to about 200 nm. The upper section layer 319A is deposited at a second temperature of about 100° C. to about 200° C., such as 150° C. The upper section layer 319A includes amorphous silicon (a-Si), silicon nitride (Si₃N₄), silicon oxide (SiO₂), silicon oxynitride (Si₂N₂O), or combinations thereof.

At operation 208, as shown in FIG. 3D, a second structure layer 310B is deposited over the first structure layer 310A. The second structure layer 310B may be deposited using sputtering. The second structure layer 310B has a thickness of about 400 nm to about 600 nm. The second structure layer 310B includes a conductive material or a non-conductive material. The conductive materials include a copper (Cu), aluminum (Al), aluminum neodymium (AlNd), molybdenum (Mo), molybdenum tungsten (MoW), or combinations thereof. The nonconductive materials include amorphous silicon (a-Si), silicon nitride (Si3N4), silicon oxide (SiO2), silicon oxynitride (Si2N2O), germanium (Ge), germanium arsenide (GeAs III or IV), or combinations thereof.

In some embodiments, an intermediate structure may be deposited between the second structure layer 310B and the first structure layer 310A. The intermediate structure material has a thickness of about 10 nm to about 20 nm. The intermediate structure material includes a chromium (Cr) material, a titanium material (Ti), or a tantalum nitride material (TaN).

At operation 210, as shown in FIG. 3E, a resist 330 is disposed and patterned on the second structure layer 310B. The resist 330 is a positive resist or a negative resist. A positive resist includes portions of the resist which, when exposed to electromagnetic radiation, are respectively soluble to a resist developer applied to the resist after the pattern is written into the resist using the electromagnetic radiation. A negative resist includes portions of the resist which, when exposed to radiation, will be respectively insoluble to the resist developer applied to the resist after the pattern is written into the resist using the electromagnetic radiation. The chemical composition of the resist 330 determines whether the resist is a positive resist or a negative resist. The portion of the second is patterned to form a pixel opening of the first sub-pixel 108A. The patterning is one of a photolithography, digital lithography process, or laser ablation process.

At operation 212, as shown in FIG. 3F, portions of the upper section layer 319A and lower section layer 319B of the first structure layer 310A and the second structure layer 310B exposed by the resist 330 are removed to form a first structure 110A and a second structure 110B. Removing portions of first structure layer 310A and the second structure layer 310B form a plurality of sub-pixels (e.g., the first sub-pixel 108A and the third sub-pixel 108C). In some embodiments, the first structure layer 310A and the second structure layer 310B exposed by the resist 330 may be removed using a wet etch process. In some embodiments, the first structure layer 310A and the second structure layer 310B exposed by the resist 330 may be removed using a low power isotropic etching. In some embodiments, the first structure layer 310A and the second structure layer 310B exposed by the resist 330 may be removed using a silicon fluoride (SF₆), fluoroform (CHF₃), or oxygen (O₂). The etch selectivity between the materials of the first structure layer 310A corresponding to the first structure 110A and the second structure layer 310B corresponding to the second structure 110B, and the etch processes to remove the exposed portions of the second structure layer 310B and the first structure layer 310A provide for a bottom surface 107 of the second structure 110B to be wider than a upper surface 105 of the first structure 110A to form an overhang extension 109A of an overhang 109.

In addition, the etch selectivity between the materials of the upper section layer 319A corresponding to the upper section 119A and the materials of the lower section layer 319B corresponding to the lower section 119B provide for a slower etch rate of the lower section 119B. The higher deposition temperature of the results in the lower section layer 319B having a higher density, resulting in a decrease in lateral etching of the lower section layer 319B. The etch rate of the upper section layer 319A is about 2 times to about 3 time greater than the etch rate of the lower section layer 319B. The resist 330 is then removed from the second structure 110B.

At operation 214, as shown in FIG. 3G, an OLED material layer 312, a cathode layer 314, and an encapsulation layer material 316 of the first sub-pixel 108A are deposited. The shadowing of the adjacent overhangs 109 provides for evaporation deposition of each of the OLED material layer 312 and the cathode layer 314. The total thickness of the OLED material layer 312 and the cathode layer 314 is from about 100nm to about 150 nm. The encapsulation layer material 316 is deposited over the cathode layer 314. A thickness of the encapsulation layer material 316 is from about 10 nm to about 50 nm. The shadowing of the adjacent overhangs 109 provides for evaporation deposition of the encapsulation layer material 316.

At operation 216, as shown in FIG. 3H, a resist 340 is disposed in the first sub-pixel 108A. The resist 340 is a positive resist or a negative resist. The chemical composition of the resist 340 determine whether the resist 340 is a positive resist or a negative resist. The resist 340 is patterned to protect the first sub-pixel 108A from the subsequent etching processes. The patterning is one of a photolithography, digital lithography process, or laser ablation process.

At operation 218, as shown in FIG. 31, portions of the OLED material layer 312, the cathode layer 314, and the encapsulation layer material 316 exposed by the resist 340 are removed to form the OLED material 112, the cathode 114, and the encapsulation layer 116 of the first sub-pixel 108A. The portions of the OLED material layer 312, the cathode layer 314, and the encapsulation layer material 316 may be removed using ashing (e.g., O₂ ashing). The surface of the anode 104 may be cleaned using UV ozone (O₃) cleaning.

At operation 220, as shown in FIG. 3J, the resist 340 is removed.

In summary, a sub-pixel circuit and method of forming a sub-pixel circuit is disclosed. The sub-pixel circuit includes adjacent overhangs having a first structure and a second structure. A bottom surface of the second structure extends past the edge of an upper surface of the first structure to form an overhang extension of the second structure. The first structure includes a lower section and an upper section disposed over the lower section. The lower section is deposited at a higher temperature that the upper section to decrease the amount of lateral etching of the lower section of the first structure. The decrease in lateral etching reduces the likelihood of an abrupt step at the interface of the anode 104 and the first structure 110A, reduces the likelihood of an exposed PIS, and thus reduces the likelihood of failure.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel circuit, comprising:
adjacent overhang structures, the overhang structures defined by an overhang extension of a second structure extending laterally past a first structure, the first structure disposed over a substrate, wherein the first structure comprises:
a lower section having a first lateral etching rate;
an upper section deposited over the lower section having a second lateral etching rate, wherein the second lateral etching rate is different from the first lateral etching rate;
an anode;
an organic light emitting diode (OLED) material disposed over the anode, wherein the OLED material extends under the adjacent overhang structures; and
a cathode disposed over the OLED material, the cathode extending under the adjacent overhang structures.

2. The sub-pixel of claim 1, wherein:
the lower section is deposited at a first temperature is about 250° C. to about 350° C.; and
the upper section is deposited at a second temperature of about 100° C. to about 200° C.

3. The sub-pixel of claim 1, wherein:
an upper surface of the second structure has a first width; and
a bottom surface of the first structure has a second width, wherein the first width of the upper surface is equal to the second width of the bottom surface.

4. The sub-pixel of claim 1, wherein the material of the upper section and the lower section include amorphous silicon (a-Si), silicon nitride (Si₃N₄), silicon oxide (SiO₂), silicon oxynitride (Si₂N₂O), or combinations thereof.

5. The sub-pixel of claim 1, wherein the material of the upper section is the same as the material of the lower section.

6. The sub-pixel of claim 1, wherein the second structure includes copper (Cu), aluminum (Al), aluminum neodymium (AlNd), molybdenum (Mo), molybdenum tungsten (MoW), or combinations thereof.

7. The sub-pixel of claim 1, wherein the second structure includes amorphous silicon (a-Si), silicon nitride (Si₃N₄), silicon oxide (SiO₂), silicon oxynitride (Si₂N₂O), germanium (Ge), germanium arsenide (GeAs III or IV), or combinations thereof.

8. A device, comprising:
a substrate;
a plurality of adjacent pixel-isolation structures (PIS) disposed over the substrate;
a plurality of sub-pixels, each sub-pixel comprising:
adjacent overhang structures, the overhang structures defined by an overhang extension of a second structure extending laterally past a first structure, the first structure disposed over a substrate; wherein the first structure comprises:
a first endpoint of a bottom surface of the first structure may extend to or past a first edge of the PIS; and
a second endpoint of the bottom surface of the first structure may extend to or past a second edge the PIS;
a lower section having a first lateral etching rate;
an upper section deposited over the lower section having a second lateral etching rate, wherein the second lateral etching rate is different from the first lateral etching rate;
an anode;
an organic light emitting diode (OLED) material disposed over the anode, wherein the OLED material extends under the adjacent overhang structures; and
a cathode disposed over the OLED material, the cathode extending under the adjacent overhang structures.

9. The device of claim 8, wherein:
the lower section is deposited at a first temperature is about 250° C. to about 350° C.; and
the upper section is deposited at a second temperature of about 100° C. to about 200° C.

10. The device of claim 8, wherein the second structure includes copper (Cu), aluminum (Al), aluminum neodymium (AlNd), molybdenum (Mo), molybdenum tungsten (MoW), or combinations thereof.

11. The device of claim 8, wherein the second structure includes amorphous silicon (a-Si), silicon nitride (Si₃N₄), silicon oxide (SiO₂), silicon oxynitride (Si₂N₂O), germanium (Ge), germanium arsenide (GeAs III or IV), or combinations thereof.

12. The device of claim 8, wherein:
an upper surface of the second structure has a first width; and
the bottom surface of the first structure has a second width, wherein the first width of the upper surface is equal to the second width of the bottom surface.

13. The device of claim 12, wherein the first width and the second width are about 0.5 μm to about 2 μm.

14. The device of claim 8, wherein the material of the upper section and the lower section include amorphous silicon (a-Si), silicon nitride (Si₃N₄), silicon oxide (SiO₂), silicon oxynitride (Si₂N₂O), or combinations thereof.

15. The device of claim 8, wherein the material of the upper section is the same as the material of the lower section.

16. A method of forming a sub-pixel circuit, comprising:
disposing a lower section layer having a first lateral etching rate over a substrate, wherein an anode is deposited on the substrate;
disposing an upper section layer having a second lateral etching rate over the lower section layer, wherein the first lateral etching rate is different from the second lateral etching rate, and wherein the lower section layer and the upper section layer form a first structure layer;
depositing a second structure layer over the first structure layer; and
removing portions of the first structure layer and the second structure layer exposed by a resist to form adjacent overhang structures defined by an overhang extension of a second structure formed from the second structure layer extending laterally past a first structure formed from the first structure layer, the first structure disposed over the substrate, wherein the first structure comprises:
an upper section formed from the upper section layer; and
a lower section formed from the lower section layer.

17. The method of claim 16, wherein:
the lower section is deposited at a first temperature is about 250° C. to about 350° C.; and
the upper section is deposited at a second temperature of about 100° C. to about 200° C.

18. The method of claim 16, wherein:
an upper surface of the second structure has a first width; and
a bottom surface of the first structure has a second width, wherein the first width of the upper surface is equal to the second width of the bottom surface.

19. The method of claim 16, further comprising:
depositing an organic light emitting diode (OLED) material layer, a cathode layer, and an encapsulation layer material; and
removing portions of the OLED material the cathode layer, and the encapsulation layer material to form an OLED material, a cathode, and an encapsulation layer.

20. The method of claim 16, wherein a material of the upper section and the lower section include amorphous silicon (a-Si), silicon nitride (Si₃N₄), silicon oxide (SiO₂), silicon oxynitride (Si₂N₂O), or combinations thereof, and wherein the material of the upper section is the same as the material of the lower section.
